(19) United States
(12) Patent Application Publication
(10) Pub. No.: US 2011/0140200 A1
(43) Pub. Date: Jun. 16, 2011

(54) Lateral Power MOSFET With Integrated Schottky Diode

(75) Inventors: Samuel J. Anderson, Tempe, AZ (US); David N. Okada, Chandler, AZ (US); Gary Dashney, Phoenix, AZ (US); David A. Shumate, Phoenix, AZ (US)

(73) Assignee: GREAT WALL SEMICONDUCTOR CORPORATION, Tempe, AZ (US)

(21) Appl. No.: 12/978,476

(22) Filed: Dec. 24, 2010

Related U.S. Application Data
(63) Continuation of application No. 12/169,349, filed on Jul. 8, 2008.

(51) Int. Cl. H01L 27/06

(52) U.S. Cl. 257/337; 257/E27.016

(57) ABSTRACT

A semiconductor device includes a substrate having a first region and a second region. The first region is electrically isolated from the second region. The semiconductor device further includes a lateral field-effect transistor (FET) disposed within the first region. The lateral FET includes a first terminal and a second terminal. The semiconductor device further includes a diode disposed within the second region, the diode including a plurality of anode regions and a plurality of cathode regions. The semiconductor device further includes a first electrical connection between the first terminal of the lateral FET and the anode regions of the diode, and a second electrical connection between the second terminal of the lateral FET and the cathode regions of the diode. The first and second electrical connections are disposed over a surface of the substrate.

### CLAIM TO DOMESTIC PRIORITY

The present application is a continuation of U.S. patent application Ser. No. 12/169,349, filed Jul. 8, 2008, and claims priority to the foregoing parent application pursuant to 35 U.S.C. §120.

### FIELD OF THE INVENTION

The present invention relates in general to electronic circuits and semiconductor devices and, more particularly, to a lateral MOSFET structure having an integrated Schottky diode.

### BACKGROUND OF THE INVENTION

MOSFETs (metal-oxide-semiconductor field-effect transistors) are commonly used in electronic circuits, such as communication systems and power supplies. Power MOSFETs are particularly useful when used as electric switches to enable and disable the conduction of relatively large currents. The current flow for MOSFETs goes between conduction contacts, e.g., from the source to the drain. The R_{DSON} (static drain-source on-resistance) should be minimized for power loss and heat dissipation. The power MOSFET switch is typically contained within a monolithic device for ease of integration and system design.

In one application, power MOSFETs are used in high frequency switching power conversion systems and class D audio amplifiers. During operation of the power MOSFET, the body diode of the MOSFET is alternately biased between conduction and blocking states. During forward bias of the body diode, electric charge is stored in neutral regions located adjacent to the PN junction of the body diode. Before returning to the body diode's blocking state, the charge must be extracted and neutralized. This process is referred to as reverse recovery.

The extraction and neutralization of the body diode charge results in power loss which lowers the power conversion efficiency of the power MOSFET. For efficient operation, amplifier systems minimize the reverse recovery process. Accordingly, the systems minimize both the amount of accumulated reverse recovery charge (Qᵣᵣ) and the characteristic time necessary to extract or neutralize the charge (tᵣᵣ).

FIG. 1 illustrates a cross-sectional view of a conventional lateral power MOSFET 10 that includes a body diode. Substrate 12 is made of p-type semiconductor material and provides structural support to the device. The following regions and layers are formed on substrate 12 using semiconductor manufacturing processes understood by those skilled in the art. The manufacturing processes include layering, patterning, doping, and heat treatment. In the layering process, materials are grown or deposited on the substrate by techniques involving thermal oxidation, nitridation, chemical vapor deposition, evaporation, and sputtering. Patterning involves the use of photolithography to mask areas of the surface and etch away undesired material. The doping process injects concentrations of dopant material by thermal diffusion or ion implantation.

Using the above semiconductor manufacturing processes, a P− well region 14 is formed on substrate 12. A body region 16 made with P-type material is formed over or above P− well region 14. P+ body 18 and N+ source region 20 are formed over or above P-type body region 16. Terminal 22 is connected to N+ source region 20 to provide the source terminal of power MOSFET 10 and includes a conductive material. An N+ drain region 24 is formed above P− well region 14 and includes a lightly doped drain (LDD) or drift region. Oxide layer 26 is formed over N+ source region 20, P-type body region 16, and N+ drift region 24. Gate region 28 is implanted within oxide layer 26. P-type regions 18 and 14, in combination with N+ region 24 form a body diode of MOSFET 10 as indicated by diode symbol 30. During operation of the MOSFET, the forward biased body diode 30 stores excess minority carrier charge in region 31. As a result of the charge build-up, when the circuit commutates the body diode, the stored charge must be extracted or neutralized before the diode can achieve its “off state.” The excess minority carriers must diffuse to the surface of the MOSFET to be extracted or recombine in the substrate to be neutralized. The depth of the stored minority carrier charge and long minority carrier lifetime of the substrate increases both tᵣᵣ and Qᵣᵣ.

FIG. 2 illustrates a conventional high frequency power conversion circuit implemented by high frequency synchronous buck regulator 32 using MOSFETs having body diodes. In one example, regulator circuit 32 operates as a step-down voltage regulator circuit. The regulator circuit includes two MOSFETs and requires two relatively short “dead times” in which to switch conduction between the first and second MOSFET. During the dead times, both MOSFETs are turned off to avoid short-circuiting the power supply.

In circuit 32, an attached load's energy supply is alternately provided by a voltage source and energy stored in an inductor. In the circuit, input voltage source 34 is connected to the drain terminal of MOSFET 35 and ground or low voltage terminal 43. The gate of MOSFET 35 is connected to an output of pulse-width modulation (PWM) control 36. PWM control 36 may include a switching regulator controller and controls the operation of MOSFETs 35 and 37 and includes logic for determining whether power should be supplied to the load by voltage source 34 or inductor 38. Both MOSFETs 35 and 37 include body diodes. The source terminal of MOSFET 35 is connected to a first terminal of inductor 38 and the drain terminal of MOSFET 37. The gate terminal of MOSFET 37 is connected to an output of PWM control 36. A second terminal of inductor 38 is connected to a first terminal of capacitor 40 and to an output 42. A second terminal of capacitor 40 is connected to a ground or low voltage source 43.

During a first phase of operation of regulator circuit 32 a threshold voltage is supplied to the gate terminal of MOSFET 35, the MOSFET is turned on and energy flows from the drain terminal of MOSFET 35 to the source terminal. MOSFET 37 is turned off. With MOSFET 35 turned on and MOSFET 37 turned off, energy is delivered from voltage source 34, through inductor 38 to output terminal 42 and to an attached load. During this phase of operation, energy is accumulated within inductor 38.

In a second phase of operation, both MOSFETs 35 and 37 are turned off. This phase is known as dead time and is the period of time during which regulator circuit 32 switches from voltage source 34 to inductor 38 as the energy supply for the load. During this operational phase, the voltage at the drain terminal of MOSFET 37 swings negative below the voltage at the source terminal of MOSFET 37 until the body diode of MOSFET 37 is forward biased. Current flows from the source to the drain of MOSFET 37 though inductor 38 to the load. When the body diode of MOSFET 37 is forward biased, it stores charge in the body diode region that needs to be removed when it is reversed biased.

In a third phase of operation, MOSFET 35 remains switched off, and a voltage is supplied to the gate terminal of MOSFET 37 to activate MOSFET 37. With MOSFET 37 turned on, the current stored within inductor 38 flows through MOSFET 37 and supplies energy to the load.

In a fourth phase of operation, MOSFET 37 is turned off by reducing the gate to source voltage of MOSFET 37 to a level below its threshold. During this time, the body diode of MOSFET 37 is forward biased and conducts current from the source to drain of MOSFET 37 through inductor 38 to the load. Stored charge is accumulated in the body diode during forward bias. When the PWM 36 supplies a signal to the gate of MOSFET 35 it starts to turn on MOSFET 35. At this time, the voltage across MOSFET 37 drain to source starts to rise and causes the body diode of MOSFET 37 to become reverse biased. The current through MOSFET 35 ramps up and the current through MOSFET 37 ramps down. Eventually, all of the current supplied to the inductor 38 is supplied from MOSFET 35. Additional current is supplied from MOSFET 35 to remove the stored charge in the body diode of MOSFET 37. Current flows from MOSFET 35 drain to source to MOSFET 37 drain to source to remove the excess stored charge in the body diode of MOSFET 37. The extra current flow to MOSFET 37 during this phase results in additional power loss for the converter circuit. The greater the IRM, trr and stored charge for the body diode of MOSFET 37, the greater the power loss.

FIG. 3 illustrates a test circuit for measuring the duration of the body diode reverse recovery process. In the circuit, PWM control 44 is coupled to the gate terminal of MOSFET 46 via adjustable resistor 45. PWM control 44 controls the operation of MOSFET 46 and includes logic for determining when to apply a threshold voltage to the gate terminal of MOSFET 46. An anode of diode 47 is coupled to the source terminal of MOSFET 46 and a cathode of diode 47 is coupled to the drain terminal of MOSFET 46. Diode 47 represents the body diode of MOSFET 46. Both the anode of diode 47 and the source of MOSFET 46 are coupled to ground or low-voltage terminal 53. The drain of MOSFET 46 is coupled to a first terminal of variable inductor 50, a source terminal of MOSFET 48 and an anode of diode 49. Diode 49 represents the body diode of MOSFET 48. The drain terminal of MOSFET 48 is coupled to the cathode of diode 49 and to a first terminal of voltage source 51. The gate terminal of MOSFET 48 is coupled to the source terminal of MOSFET 48 to bias MOSFET 48 into an off (or non-conducting) state. When operating the test circuit, voltage is applied from PWM 44 to a level greater than the threshold voltage of MOSFET 46. The applied voltage turns on MOSFET 46 and current flows from voltage source 51, through inductor 50, through MOSFET 46 to ground. The current flow stores energy in inductor 50. PWM 44 turns off MOSFET 46 and current continues to flow through inductor 50 and forward biases body diode 49. Current flows in the upper current loop of body diode 49 and inductor 50. PWM 44 turns on MOSFET 46 again and conducts current. By controlling the input to MOSFET 46, body diode 49 is commutated such that the forward current through the diode is reduced at a specified rate of change (di/dt).

FIG. 4 illustrates an example output of the test circuit of FIG. 3 showing current flow through body diode 49 as diode current decreases over time. As shown in FIG. 4, the diode current is initially positive, but is decreased and eventually becomes negative. In the forward conduction zone, body diode 49 is conductive. As the diode current becomes negative (shown as point 59 on FIG. 4), body diode 49 continues conducting. At point 59, an ideal diode would stop conducting electricity and show an output current value of 0 A. However, with reference to FIG. 4, body diode 49 continues to conduct for a period of time shown as tᵣᵣ on FIG. 4. The duration of tᵣᵣ is determined by Qᵣᵣ—the amount of charge built-up within body diode 49. Because it takes an extended period of time for body diode 49 to stop conducting after becoming reverse biased, the switching process for conventional power MOSFET converter systems is inefficient. In one example test, the reverse recovery time of the circuit is approximately 220 ns. In the example, the combination of a large max reverse leakage current (I_{RM}) of approximately 6A and a relatively large tᵣᵣ results in a large Qᵣᵣ—the amount of charge stored within the body diode. As the amount of stored charge increases, the efficiency of the device is decreased and power loss is increased.

By minimizing the amount of charge build-up within the body diode and the amount of time necessary to remove the build-up charge, the efficiency of the device can be increased.

### SUMMARY OF THE INVENTION

In one embodiment, the present invention is a semiconductor device comprising a first substrate including a first semiconductor material, an insulating layer disposed over an entire surface of the first substrate, and a second substrate disposed over a surface of the insulating layer, wherein the insulating layer electrically isolates the second substrate from the first substrate. The second substrate includes a second semiconductor material. The semiconductor device further comprises a plurality of insulating trenches disposed in the second substrate and extending down to the insulating layer, wherein the insulating trenches electrically isolate a first region of the second substrate from a second region of the second substrate. The semiconductor device further comprises a lateral metal-oxide-semiconductor field-effect transistor (MOSFET) disposed within the first region, and a Schottky diode disposed within the second region. The semiconductor device further comprises a first electrical connection that electrically connects a first terminal of the lateral MOSFET to a plurality of anode regions of the Schottky diode, and a second electrical connection that electrically connects a second terminal of the lateral MOSFET to a plurality of cathode regions of the Schottky diode, wherein first and second electrical connections are disposed over a surface of the second substrate.

In another embodiment, the present invention is a semiconductor device comprising a first substrate, an insulating layer disposed over the first substrate, and a second substrate disposed over the insulating layer, wherein the insulating layer provides electrical isolation between the first and second substrates. The semiconductor device further comprises an insulating trench disposed in the second substrate down to the insulating layer, wherein the insulating trench electrically isolates a first region of the second substrate from a second region of the second substrate. The semiconductor device further comprises a lateral metal-oxide-semiconductor field-effect transistor (MOSFET) disposed within the first region, and a Schottky diode disposed within the second region. The semiconductor device further comprises a first electrical connection that electrically connects a first terminal of the lateral MOSFET to a plurality of anode regions of the Schottky diode, and a second electrical connection that electrically connects a second terminal of the lateral MOSFET to a plurality of cathode regions of the Schottky diode. The first and second electrical connections are disposed over a surface of the second substrate.

In another embodiment, the present invention is a semiconductor device comprising a first substrate including a first semiconductor material, an insulating layer formed over an entire surface of the first substrate, and a second substrate including a second semiconductor material disposed over the insulating layer, wherein the insulating layer provides electrical isolation between the first and second substrates. The semiconductor device further includes an insulating trench formed through the second substrate to the insulating layer to form first and second electrically isolated regions, a lateral field-effect transistor (FET) formed within the first electrically isolated region, and a diode formed within the second electrically isolated region. The semiconductor device further includes a first electrical connection between a first terminal of the lateral FET and a plurality of anode regions of the diode, and a second electrical connection between a second terminal of the lateral FET and a plurality of cathode regions of the diode. The first and second electrical connections are formed over a surface of the second substrate.

In another embodiment, the present invention is a semiconductor device comprising a substrate having a first region and a second region. The first region is electrically isolated from the second region. The semiconductor device further comprises a lateral field-effect transistor (FET) disposed within the first region. The lateral FET includes a first terminal and a second terminal. The semiconductor device further comprises a diode disposed within the second region, wherein the diode includes a plurality of anode regions and a plurality of cathode regions. The semiconductor device further comprises a first electrical connection between the first terminal of the lateral FET and the anode regions of the diode and a second electrical connection between the second terminal of the lateral FET and the cathode regions of the diode. The first and second electrical connections are disposed over a surface of the substrate.

### BRIEF DESCRIPTION OF THE DRAWINGS

FIG. 1 illustrates a cross-sectional view of a conventional lateral MOSFET illustrating a location of the body diode of the MOSFET;

FIG. 2 is an equivalent circuit for a conventional synchronous buck power converter circuit with MOSFETs having body diodes;

FIG. 3 is an equivalent circuit for generating MOSFET body diode reverse recovery measurements having an energy source and a MOSFET with a body diode;

FIG. 4 is a chart showing a typical reverse recovery waveform of a body diode of a MOSFET generated by the equivalent circuit of FIG. 3;

FIG. 5 is an equivalent circuit for a regulator circuit with an integrated discrete Schottky diode for minimizing the reverse recovery time of the body diode of the MOSFET;

FIG. 6 is a chart showing the typical reverse recovery waveform for a lateral power MOSFET having a coupled Schottky diode as implemented in FIG. 5;

FIG. 7 illustrates a cross-sectional representation of a lateral power MOSFET formed over a semiconductor substrate;

FIG. 8 illustrates a cross-sectional representation of a Schottky diode formed over a semiconductor substrate;

FIGS. 9a-9f illustrate a method of manufacturing a lateral power MOSFET with an integrated Schottky diode;

FIG. 10 illustrates a cross-sectional view of a lateral power MOSFET with an integrated Schottky diode and including etched passivation for wirebonding;

FIG. 11 illustrates the lateral power MOSFET with integrated Schottky diode of FIG. 10 configured for the formation of solder bump interconnections;

FIG. 12 illustrates a circuit layout for a dual monolithic lateral power MOSFET with integrated Schottky diode structure;

FIG. 13 illustrates an example configuration of dual monolithic silicon-on-insulator lateral MOSFETs with integrated Schottky diodes showing example device interconnection terminals;

FIG. 14 illustrates a top view of a substrate including dual monolithic lateral MOSFETs with integrated Schottky diodes, the substrate is configured for wire bond interconnection;

FIG. 15 illustrates a top view of a substrate including dual monolithic lateral MOSFETs with integrated Schottky diodes, the substrate is configured for solder bump interconnection;

FIGS. 16a-16b illustrate topological arrangements for lateral power MOSFETs with integrated Schottky diodes;

FIGS. 17a-17b illustrate half and full-bridge audio amplifiers implemented using lateral power MOSFETs with integrated Schottky diodes;

FIG. 18 illustrates a cross-sectional view of a second embodiment of a lateral power MOSFET with an integrated Schottky diode;

FIGS. 19a and 19b illustrate views of a third embodiment of a lateral power MOSFET with an integrated Schottky diode;

FIG. 20 illustrates a cross-sectional view of a substrate having insulation-filled trenches for forming multiple monolithic lateral power MOSFETs with integrated Schottky diodes;

FIGS. 21a and 21b illustrate dual lateral power MOSFETs with integrated Schottky diodes that are formed monolithically over a substrate and are electrically isolated by insulation trenches; and

FIGS. 22a and 22b illustrate an H-bridge driver including four lateral power MOSFETs with integrated Schottky diodes formed over a substrate.

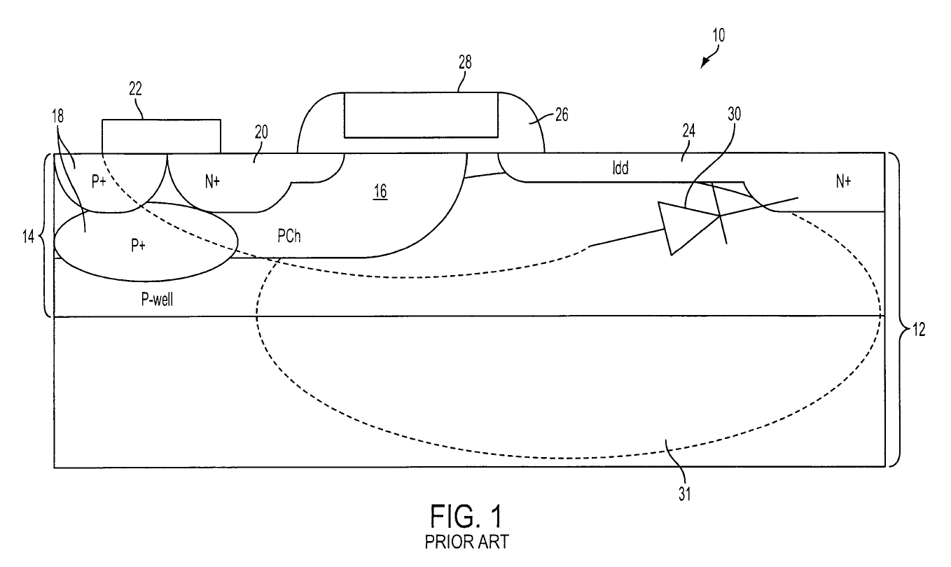

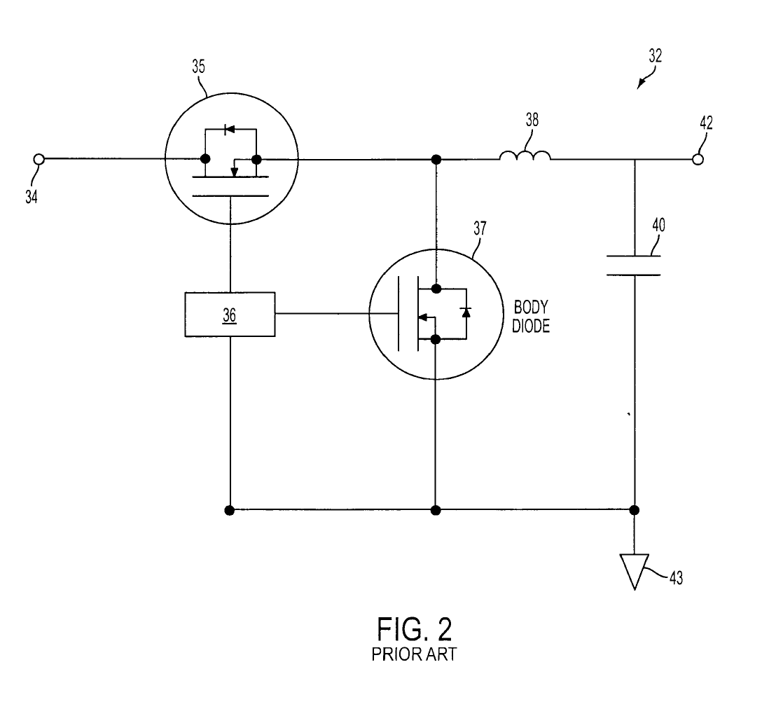

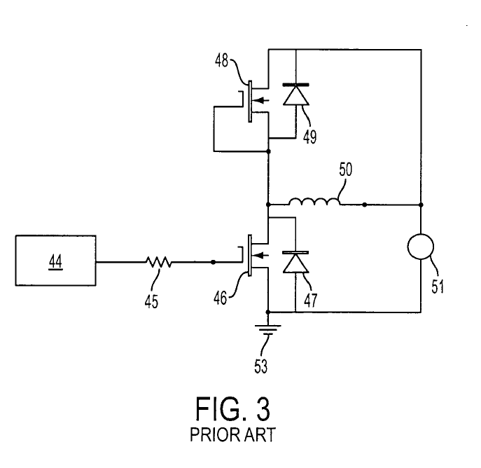

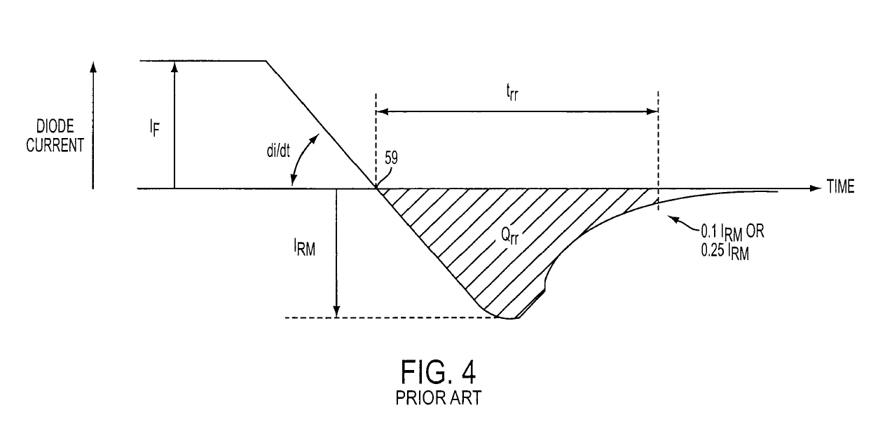

### DETAILED DESCRIPTION OF THE DRAWINGS

The present invention is described in one or more embodiments in the following description with reference to the Figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

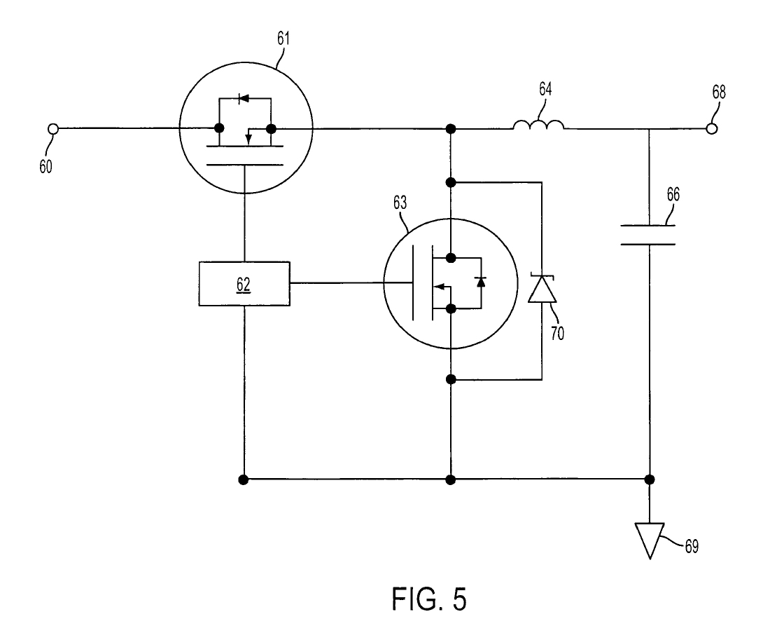

Referring to FIG. 5, a regulator circuit with a Schottky diode for minimizing reverse recovery losses is illustrated. In the circuit, input voltage 60 is connected to the source terminal of MOSFET 61. The gate of MOSFET 61 is connected to an output of PWM control 62. PWM control 62 controls the operation of MOSFETs 61 and 63 and includes logic for determining whether power should be supplied by voltage source 60 or inductor 64. The drain terminal of MOSFET 61 is connected to a first terminal of inductor 64 and the drain terminal of MOSFET 63. Both MOSFETs 61 and 63 include a body diode formed within the substrates of the MOSFETs. The gate terminal of MOSFET 63 is connected to an output of PWM control 62. A second terminal of inductor 64 is connected to a first terminal of capacitor 66 and to an output 68. Schottky diode 70 is connected between the source and drain terminals of MOSFET 63. A second terminal of capacitor 66 is connected to a ground or low-voltage terminal 69.

In this circuit configuration, Schottky diode 70 minimizes the reverse recovery losses associated with the build-up of minority carrier charge within the body diode of MOSFET 63. Schottky diode 70 has a lower forward voltage drop than the PN-junction body diode of MOSFET 63. As a result, the current normally carried by the body diode of MOSFET 63 flows primarily through Schottky diode 70 minimizing the amount of charge build-up within the body diode of MOSFET 63. For this circuit, tᵣᵣ is further minimized due to the quicker reverse recovery of Schottky diode 70. In some cases, the tᵣᵣ with integrated Schottky diode 70 is on the order of tens of nanoseconds.

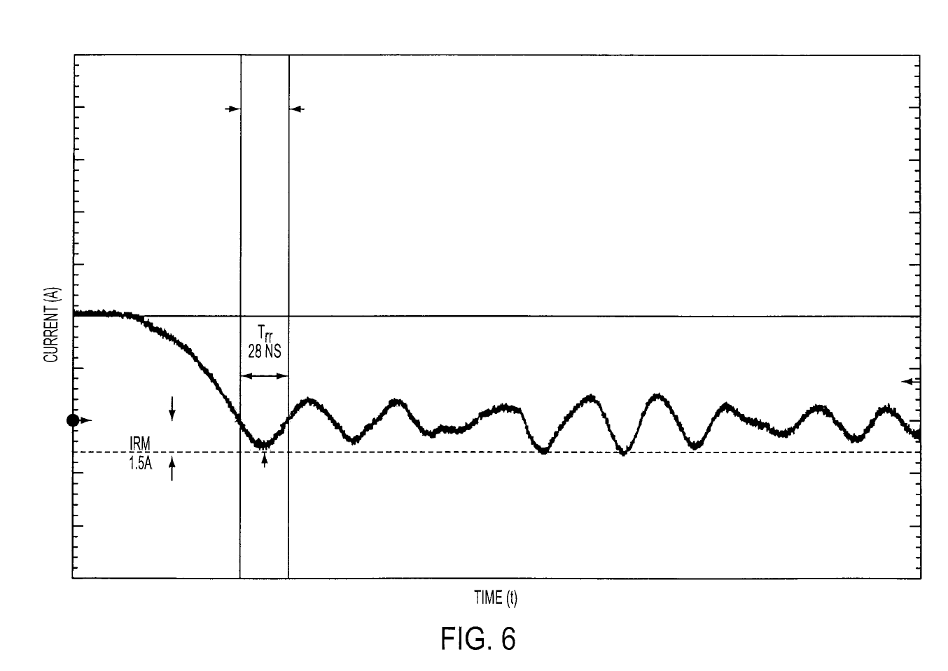

FIG. 6 illustrates a measured reverse recovery waveform for a lateral power MOSFET with a Schottky diode. Tᵣᵣ is approximately 28 ns. A small I_{RM} of approximately 1.5 A and the relatively short tᵣᵣ results from the small amount of charge stored within the body diode of the MOSFET.

Although the addition of Schottky diode 70 improves the efficiency of the converter circuit, discrete Schottky diodes have drawbacks. The diode takes up valuable board space and increases circuit complexity. As a result, the maximum size for the MOSFET is reduced which similarly reduces R_{DSON} for the entire package. In the case of external Schottky diodes, the package and board inductance between the MOSFET and the Schottky diode results in poor electrical coupling during switching. The poor electrical coupling limits the capacity of the Schottky diode to divert current from the body diode of the MOSFET.

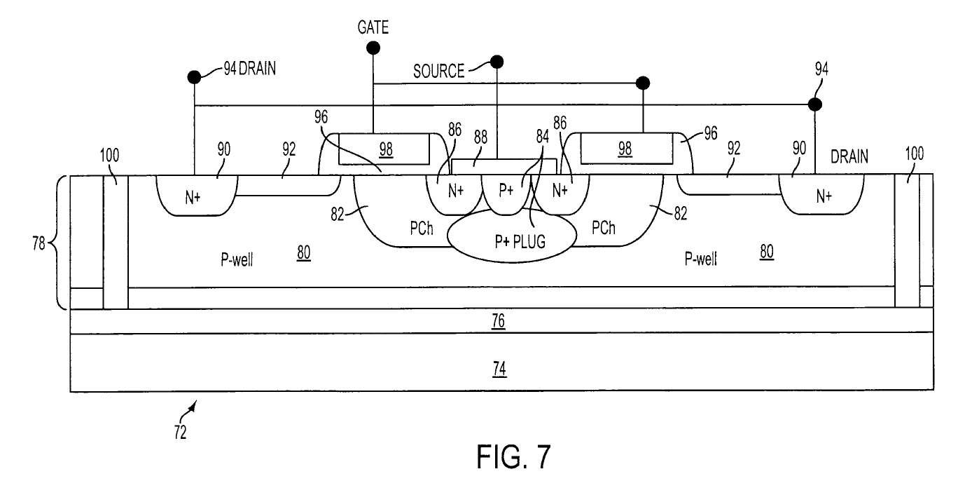

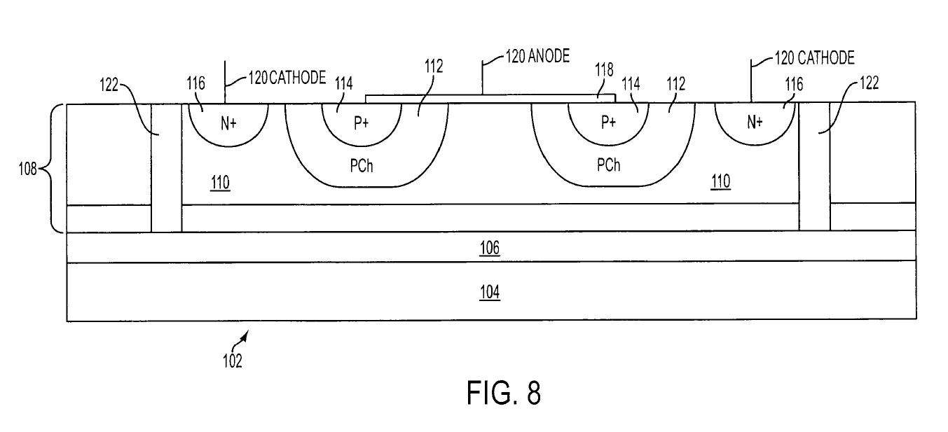

FIGS. 7 and 8 illustrate cross-sectional views of a lateral power MOSFET and a Schottky diode formed monolithically onto the same substrate. Both devices are formed over a silicon-on-insulator (SOI) substrate. Silicon trenches filled with silicon dioxide (SiO2) are formed within the substrate to electrically isolate the lateral power MOSFET and the Schottky diode. By isolating the MOSFET and the diode, a plurality of isolated lateral power MOSFETs and Schottky diodes may be formed over a single substrate. Chip metallization is then used to couple each of the Schottky diodes to one or more of the lateral power MOSFETs. The structure may be used in all lateral power device structures that include MOSFETs and require fast reverse recovery.

Turning to FIG. 7, a cross-sectional view of lateral power MOSFET 72 is illustrated. Substrate 74 is made of p-type semiconductor material and provides structural support to the device. SiO2 layer 76 is formed over substrate 74 using a chemical vapor deposition, physical vapor deposition or other deposition or implantation process. SiO2 layer 76 provides electrical insulation between substrate 74 and the devices formed over substrate 74 above SiO2 layer 76. The insulation minimizes the parasitic device capacitance that would otherwise be generated by substrate 74.

A second p-type substrate 78 is bonded over SiO2 layer 76. In one example bonding process, a layer of SiO2 is formed over a surface of a separate substrate 78. Substrate 78 is then inverted and the layer of SiO2 formed over substrate 78 is bonded to SiO2 layer 76 to connect substrates 74 and 78. After bonding, substrate 78 may be planarized to a particular height, depending upon the application. In one embodiment, the height of substrate 78 is reduced by grinding followed by a chemical-mechanical planarization (CMP) process.

P− well region 80 is formed within substrate 78. Body region 82 made with P-type material is formed over or above P− well region 80. P+ body 84 and N+ source region 86 are formed over or above P-type body region 82. In one embodiment, P+ body 84 includes a P+ plug region formed below N+ source region 86. Terminal 88 includes a conductive material and is deposited over N+ source region 86 and P+ body 84 to provide the source terminal of power MOSFET 72. N− drift region 92 and N+ drain region 90 are formed above P− well region 80. Terminal 94 is connected to N+ drain region to form a drain terminal for MOSFET 72. Oxide layer 96 is formed over N+ source region 86, P-type body region 82, and N− drift region 92. Gate region 98 is formed over oxide layer 96. Trenches are formed in substrate 78 using a laser drilling, or other etching process to expose a portion of SiO2 layer 76. Insulative material such as SiO2 is deposited into the trenches to form insulating trenches 100. Trenches 100 surround the MOSFET device and electrically insulate the MOSFET from other devices formed over substrate 74.

FIG. 8 illustrates a cross-sectional view of Schottky diode 102 including substrate 104. SiO2 layer 106 is formed over substrate 104 and acts as an electrical insulator. N− well region 110 is formed within substrate 108. Anode regions 112 made with P-type material are formed over or above N− well region 110. P+ regions 114 are formed over or above P-type anode regions 112. N+ cathode regions 116 are formed within N− well region 110 using an implantation or other deposition process. Metal layer 118 is deposited over P+ regions 114 to form the metal anode of Schottky diode 102. Metal layer 118 includes a conductive material such as titanium (Ti), nickel (Ni), platinum (Pt), and tungsten (W) and may be formed as a metal-silicide or metal-Si layer. Terminals 120 are connected to metal layer 118 and to N+ cathode regions 116. Terminals 120 are connected to other devices formed over substrate 104, for example to interconnect Schottky diode 102 with other lateral power MOSFETs. Trenches are formed in substrate 108 using a laser drilling, or other etching process to expose a portion of SiO2 layer 106. An insulative material such as SiO2 is deposited into the trenches to form insulating trenches 122. Trenches 122 surround the Schottky diode and electrically insulate the diode from other structures formed over substrate 104.

By combining the MOSFET and the diode on a single monolithic substrate, the overall board space and component count for a device can be reduced by simplifying its manufacturing process. Also, because the two devices are in close proximity, chip metallization can be used to connect the lateral power MOSFET and the Schottky diode. The chip metallization provides a low resistance and low inductance connection mechanism between the two components allowing for efficient coupling of the diode to the MOSFET under fast switching conditions such as those found in synchronous buck DC-to-DC converters. Finally, multiple isolated lateral power MOSFETs with one or more coupled Schottky diodes can be monolithically integrated—again providing for flexible package and device design.

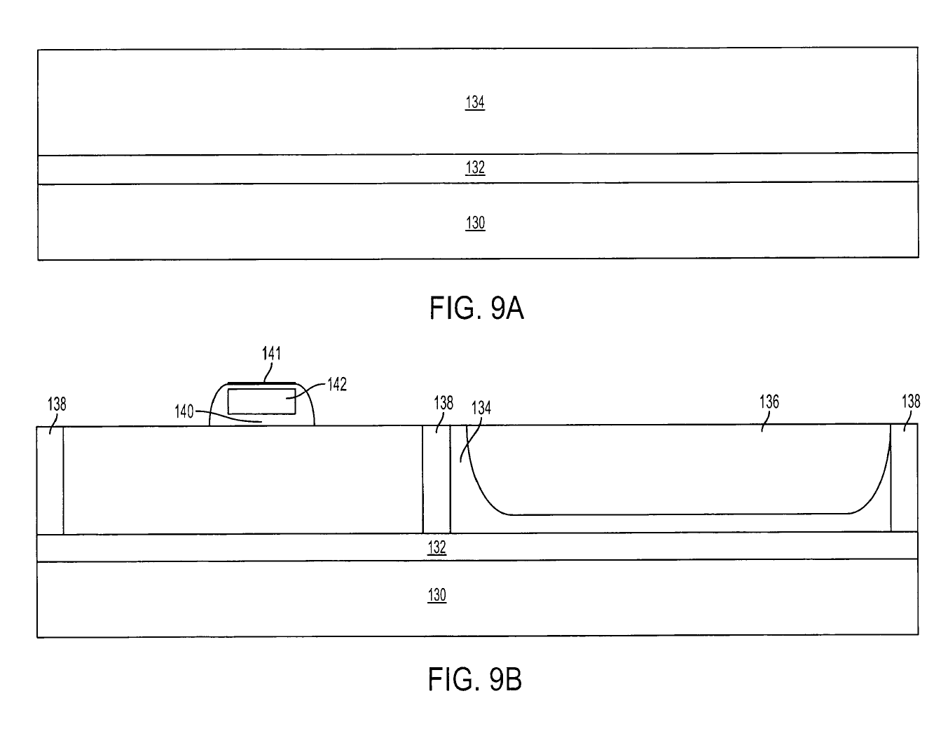

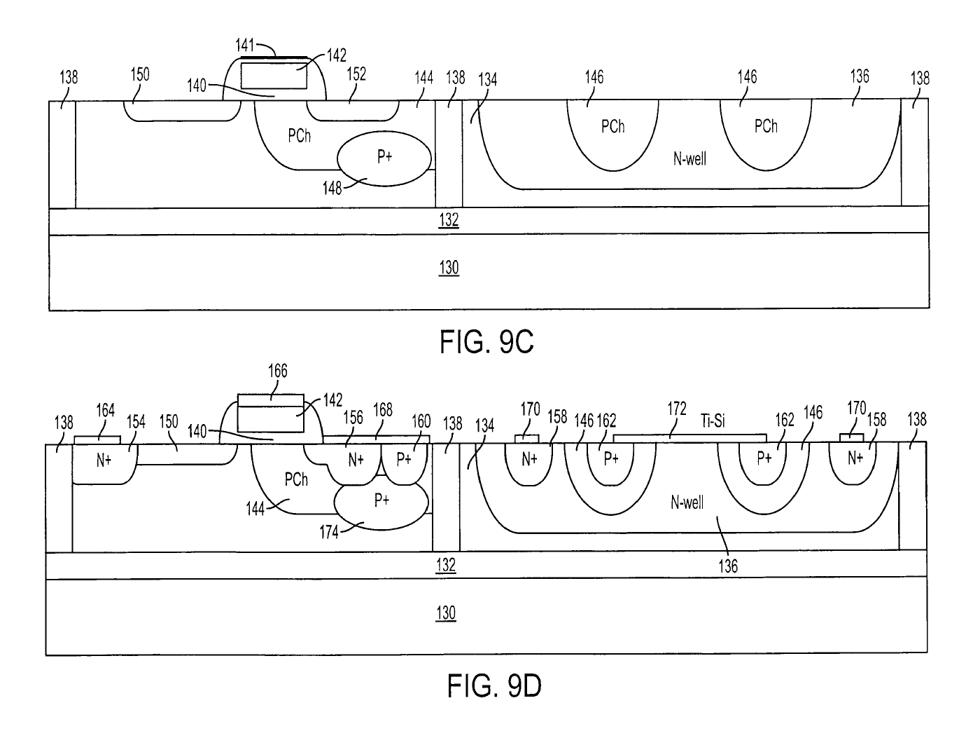

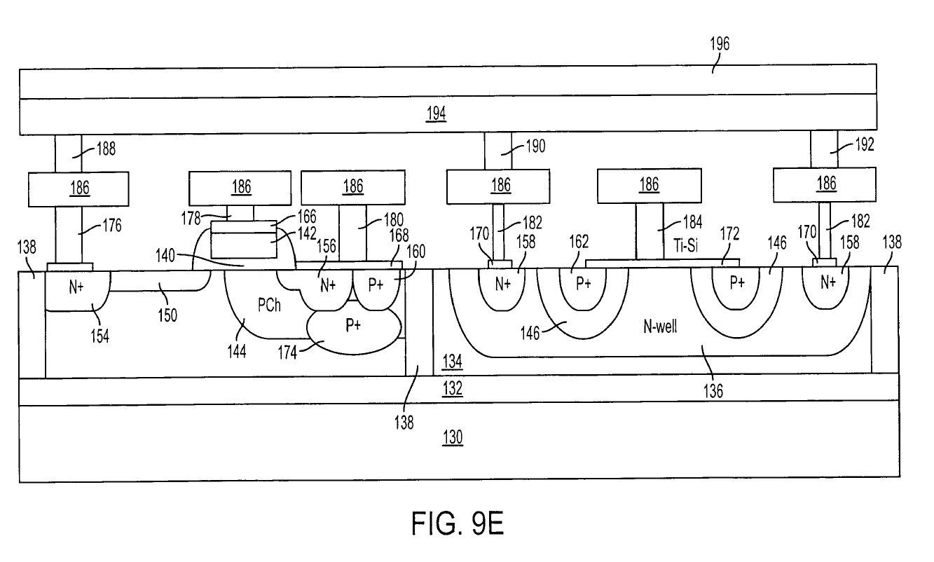

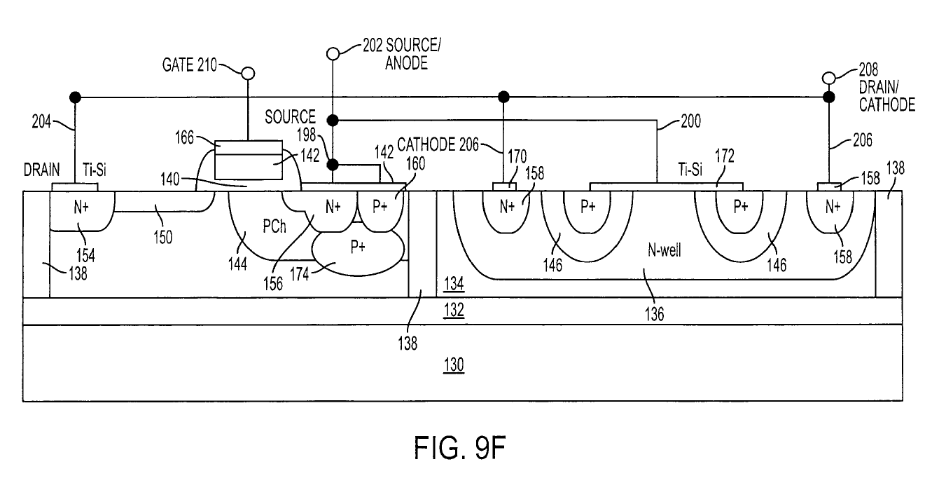

FIGS. 9a-9f illustrate a method of fabricating a lateral power MOSFET with an integrated Schottky diode. Turning to FIG. 9a, substrate 130 includes a p-type substrate material such as a doped Si semiconductor substrate. A layer of SiO2 is formed over a surface of substrate 130 using a CVD, PVD or other deposition or thermal oxidation process. Over a surface of a second wafer, another layer of SiO2 is formed. The second wafer is then inverted and the two SiO2 layers are bonded together to form SiO2 layer 132. In one embodiment, after bonding, the thickness of SiO2 layer 132 is approximately 2 μm and the second wafer forms p-type device layer 134. Device layer 134 may be thinned using a CMP or other thinning process to control the height of device layer 134, depending upon the application.

Turning to FIG. 9b, N-well 136 is formed using photolithography and implantation. Trenches are formed in device layer 134 using a laser drilling or other etching process. An insulator such as SiO2 is deposited into the trenches to form insulating trenches 138. Alternatively, trenches 138 may be formed by a thermal oxidation process. Trenches 138 provide electrical insulation to the devices formed within device layer 134. Gate oxide 140 is thermally grown over one of the electrically insulated portions of device layer 134 to form a gate junction of the MOSFET. Gate polycide 142 is formed over gate oxide 140 to form a gate terminal. Gate cap 141 includes an oxide layer and is deposited over gate polycide 142 using a high-temperature low-pressure deposition (HLD) process. In one embodiment, gate cap 141 includes TetraEthvlOrthosilicate (TEOS) and has a thickness of approximately 1500 Å.

Turning to FIG. 9c, a plurality of doped regions is formed within device layer 134 using photolithography and implantation processes. P-channel regions 144 and 146 are formed within device layer 134. P+ plug 148 is formed next to and partially overlapping P-channel region 144. N-type LDD regions 150 and 152 are formed partially beneath gate oxide 140. N-type LDD region 152 is formed within p-channel 144.

Turning to FIG. 9d, device layer 134 is further doped to form additional N and P-type regions. N+ regions 154, 156, and 158 are formed using a photolithography and implantation process. N+ region 154 forms a drain of the MOSFET. N+ regions 158 form cathodes of the diode. P+ regions 160 and 162 are formed within device layer 134. P+ region 160 is formed within P-channel region 144. N+ region 156 and P+ region 160 form a source of the MOSFET. P+ regions 162 are formed within P-channel regions 146. A conductive layer is deposited over device layer 134 and patterned and etched to form interconnect pads 164, 166, 168, 170, and 172. The conductive layer may include a metal such as Ti, Ni, Pt, W, Gold (Au), or Silver (Ag) and may be formed as a metal-silicide or metal-Si layer. Interconnect pad 172 forms the Anode terminal of the diode. P+ plug 174 is formed beneath N+ region 156 and P+ region 160.

Turning to FIG. 9e, an interconnect structure is formed over substrate 130. Interlayer dielectric material (not shown) is deposited over substrate 130. The interlayer dielectric is patterned and etched and conductive material such as W, Ti, Copper (Cu), Ag, aluminum (Al), or Au is deposited into the etched portions to form contacts 176, 178, 180, 182 and 184. Metal layer 186 is deposited over substrate 130 and electrically connected to contacts 176, 178, 180, 182 and 184. Metal layer 186 is patterned and etched to form a plurality of conductive elements that are connected to the contacts. A layer of inter-metal dielectric material (not shown) is deposited over metal layer 186. The inter-metal dielectric material is etched. Conductive material such as W, Cu, Au, Al, or Ag is deposited into the etched portions of the inter-metal dielectric to form vias 188, 190, and 192. Metal layer 194 is deposited over vias 188, 190, and 192 and the inter-metal dielectric layer. Metal layer 194 includes a conductive material such as Cu, Au, Al, Ti, or Ag and is patterned and etched. Passivation layer 196 is deposited or formed over metal layer 194 to provide physical support and electrical insulation to the device. Passivation layer 196 includes silicon dioxide (SiO2), silicon oxynitride (SiON), silicon nitride (SixNy), polyimide (PI), benzocyclobutene (BCB), polybenzoxazole (PBO), or other insulating material and is patterned and etched to expose portions of metal layer 194.

FIG. 9f illustrates an equivalent interconnect structure for forming a lateral power MOSFET with an integrated Schottky diode. Source terminal 198 of the MOSFET is connected to anode terminal 200 of the Schottky diode to form a combined source/anode terminal 202. Drain terminal 204 of the MOSFET is connected to the cathode terminals 206 of the Schottky diode to form a combined drain/cathode terminal 208. Finally, gate terminal 210 is connected to gate interconnect pad 166.

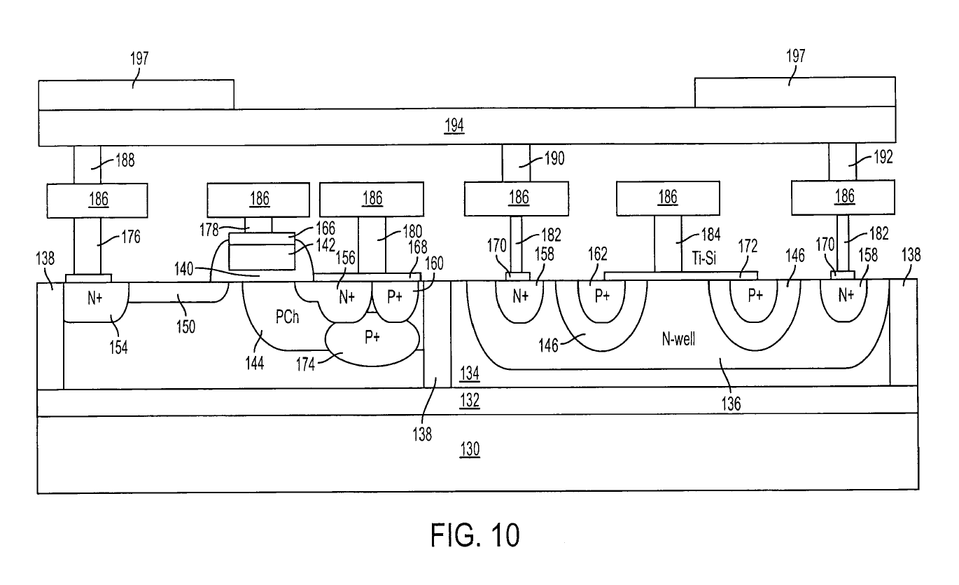

FIG. 10 illustrates a cross-sectional view of a lateral power MOSFET with integrated Schottky diode including etched passivation for wirebonding. Substrate 130 includes a p-type substrate material such as a doped Si semiconductor substrate. A layer of SiO2 is formed over a surface of substrate 130. Over a surface of a second wafer, another layer of SiO2 is formed. The second wafer is then inverted and the two SiO2 layers are bonded together to form SiO2 layer 132. The second wafer forms p-type device layer 134. Device layer 134 may be thinned using a CMP or other thinning process to control the height of device layer 134, depending upon the application. N-well 136 is formed using photolithography and implantation. Trenches are formed in device layer 134 and an insulator such as SiO2 is deposited into the trenches to form insulating trenches 138. Trenches 138 provide electrical insulation to the devices formed within device layer 134. Gate oxide 140 is thermally grown over one of the electrically insulated portions of device layer 134 to form the gate oxide of the MOSFET. Gate polycide 142 is formed over oxide 140 to form a gate terminal. Gate cap 141 includes an oxide layer and is deposited over gate polycide 142 using a HLD process. In one embodiment, gate cap 141 includes TEOS and has a thickness of approximately 1500 Å.

A plurality of doped regions is formed within device layer 134 using photolithography and implantation processes. P-channel regions 144 and 146 are formed within device layer 134. P+ plug 148 is formed next to and partially overlapping P-channel region 144. N-type LDD regions 150 and 152 are formed partially beneath gate oxide 140. N-type LDD region 152 is formed within p-channel 144. N+ regions 154, 156, and 158 are formed using a photolithography and implantation process. N+ region 154 forms a drain of the MOSFET. N+ regions 158 form cathodes of the diode. P+ regions 160 and 162 are formed within device layer 134. P+ region 160 is formed within P-channel region 144. N+ region 156 and P+ region 160 form a source of the MOSFET. P+ regions 162 are formed within P-channel regions 146. A conductive layer is deposited over device layer 134 and patterned and etched to form interconnect pads 164, 166, 168, 170, and 172. The conductive layer may include a metal such as Ti, W, Pt, Al, Au, Ag, and may be formed as a metal-silicide or metal-Si layer. Interconnect pad 172 forms the anode terminal of the diode. P+ plug 174 is formed beneath N+ region 156 and P+ region 160.

An interconnect structure is formed over substrate 130. Interlayer dielectric material (not shown) is deposited over substrate 130. The interlayer dielectric is patterned and etched and conductive material such as W, Ti, Al, Cu, Ag, or Au is deposited into the etched portions to form contacts 176, 178, 180, 182 and 184. Metal layer 186 is deposited over substrate 130 and electrically connected to contacts 176, 178, 180, 182 and 184. Metal layer 186 is patterned and etched to form a plurality of conductive elements that are connected to the contacts. The conductive elements may be patterned to form a single ‘u’ shaped element. A layer of inter-metal dielectric material (not shown) is deposited over metal layer 186. The inter-metal dielectric material is etched. Conductive material such as W, Al, Ti, Cu, Au, or Ag is deposited into the etched portions of the inter-metal dielectric to form vias 188, 190, and 192. Metal layer 194 is deposited over vias 188, 190, and 192 and the inter-metal dielectric layer. Metal layer 194 includes a conductive material such as Cu, Al, Ti, Au, or Ag and is patterned and etched. Passivation layer 197 is deposited or formed over metal layer 194 to provide physical support and electrical insulation to the device. Passivation layer 197 includes SiO2, SiON, SixNy, PI, BCB, PBO, or other insulating material. With reference to FIG. 10, passivation layer 197 is etched to expose a portion of metal layer 194. Wire bonds can be joined to the exposed portions of metal layer 194 to interconnect the lateral power MOSFET and integrated Schottky diode to other system components. The wirebonds include a conductive material such as Al, Cu, Au and Ag and are formed by bonding a thin wire of conductive material to the exposed portion of metal layer 194 and connecting the wire bond to other system components. A combination of heat and/or pressure may be used to bond the wire to metal layer 194.

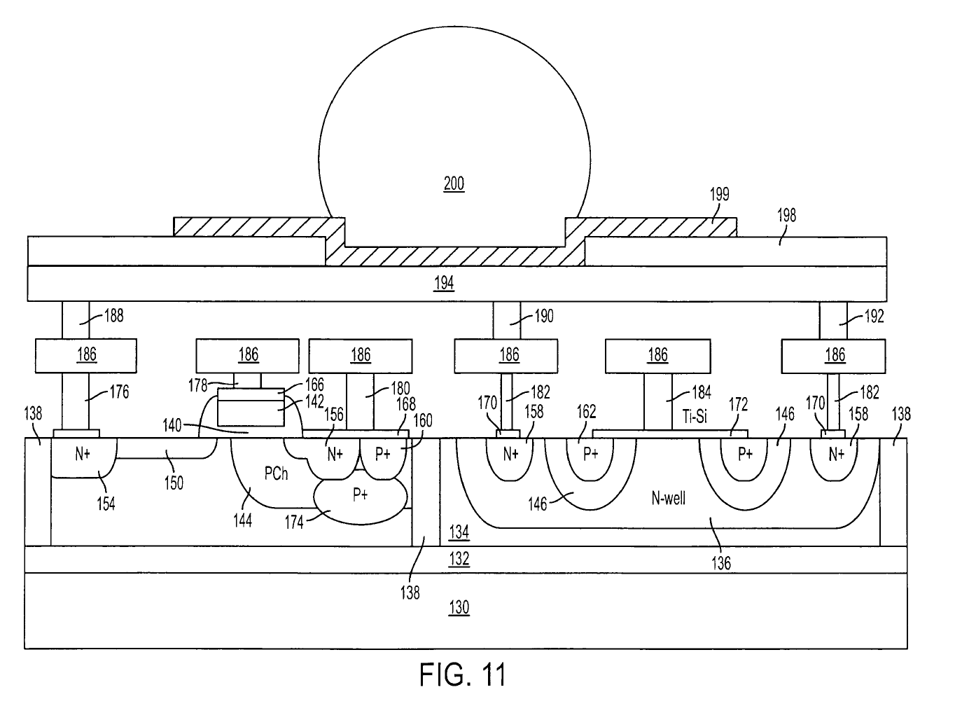

FIG. 11 illustrates the lateral power MOSFET with integrated Schottky diode of FIG. 10 configured for the formation of solder bump interconnections. Passivation layer 198 is etched or patterned to expose portions of metal layer 194 and to form a plurality of interconnect sites. An optional under-bump metallization (UBM) 199 is formed over the exposed portions of metal layer 194. UBM 199 includes one or more layers of conductive materials including Ti, Cu, Al, Au, Ag, or nickel vanadium (NiV). UBM 199 is formed by any suitable process, including first etching a portion of metal layer 194 and then applying one or more metal layers using a vacuum deposition by evaporation or sputtering process or a chemical plating process. In one embodiment, UBM 199 includes a wetting layer, barrier layer, and adhesive layer. An electrically conductive solder material is deposited over the exposed portion of metal layer 194 using an evaporation, electrolytic plating, electroless plating, ball drop, or screen printing process. The solder material can be any metal or electrically conductive material, e.g., Sn, Pb, Ni, Au, Ag, Cu, Bi, and alloys thereof. For example, the solder material can be eutectic Sn/Pb, high lead, or lead free. The solder material is reflowed by heating the solder material above its melting point to form bump 200. In some applications, solder bump 200 is reflowed a second time to improve electrical connection to UBM 199 and metal layer 194. After formation, additional system components can be connected to bump 200. In alternative embodiments, other interconnection structures such as Cu pillar bumps, or electroless Ni with Au flash can be formed over the exposed portions of metal layer 194 or UBM 199 for interconnection with other system components.

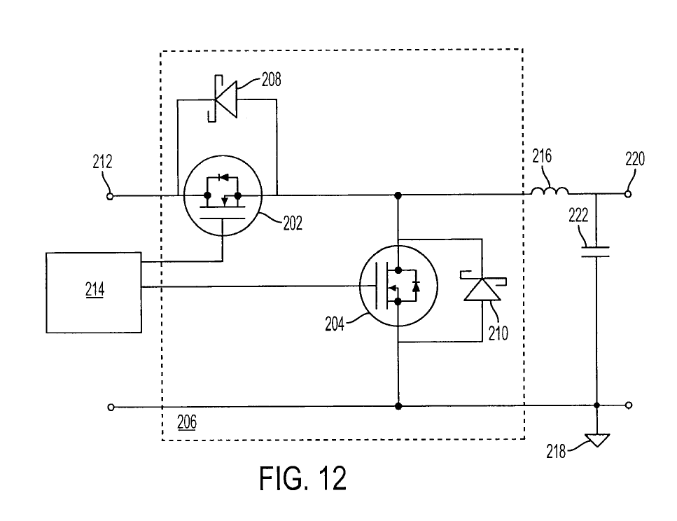

FIG. 12 illustrates a circuit layout for a dual monolithic lateral power MOSFET with integrated Schottky diode. MOSFETs 202 and 204 are formed monolithically over substrate 206. MOSFET 202 includes integrated Schottky diode 208 and MOSFET 204 includes integrated Schottky diode 210. Input 212 is connected to the drain terminal of MOSFET 202 and the anode of diode 208. The output of PWM control 214 is connected to the gate terminals of MOSFETs 202 and 204. PWM control 214 controls the operation of MOSFETs 202 and 204 and includes logic for determining whether power should be supplied to the load or output 220 by input 212 or inductor 216. The source of MOSFET 202 is connected to the cathode of diode 208, the drain terminal of MOSFET 204, the cathode of diode 210 and to a first terminal of inductor 216. A source of MOSFET 204 is connected to the anode of diode 210 and to a ground or low voltage connection 218. A second terminal of inductor 216 is connected to output 220 and a first terminal of capacitor 222. A second terminal of capacitor 222 is connected to ground or low voltage terminal 218.

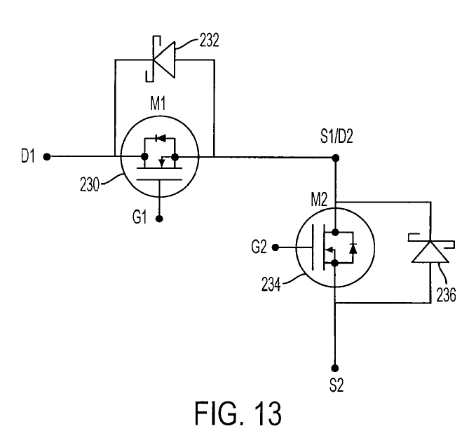

FIG. 13 illustrates an example configuration of dual monolithic silicon-on-insulator lateral MOSFETs with integrated Schottky diodes showing example device connection terminals. MOSFET 230 has integrated Schottky diode 232. MOSFET 234 has integrated Schottky diode 236. The drain terminal of MOSFET 230 is connected to the cathode of diode 232 and operates as a first drain input D1 for the dual integrated MOSFET device. The gate terminal of MOSFET 230 operates as a first gate G1 for the device. The source terminal of MOSFET 230 is connected to the anode of diode 232, cathode of diodes 236, and the drain terminal of MOSFET 234 to form a first source and a second drain terminal S1/D2 for the device. The gate terminal of MOSFET 234 operates as a second gate G2 for the device. Finally, the source terminal of MOSFET 234 is connected to the anode of diode 236 and operates as a second source terminal S2 for the device.

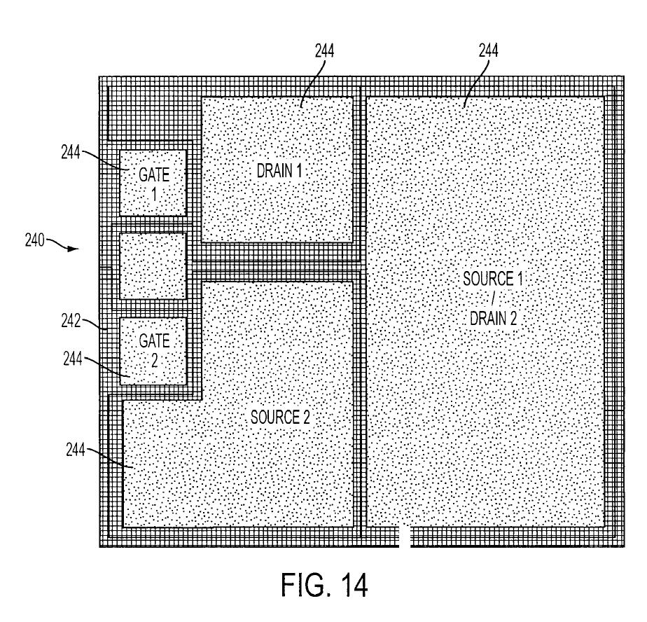

FIG. 14 illustrates a top view of a substrate including dual monolithic lateral MOSFETs with integrated Schottky diodes, the substrate is configured for wire bond interconnection. In one embodiment, the integrated lateral power MOSFETs having integrated Schottky diodes of FIG. 13 are formed over a surface of substrate 240 using the present methods. Passivation film 242 (shown as 197 on FIG. 10) is formed over a top surface of substrate 240. Passivation film 242 is patterned or etched to expose portions of metal layer 244. The exposed portions of metal layer 244 include a plurality of interconnect sites for connecting to the circuit formed on substrate 240. Additional layers of conductive material may be deposited over the etched portions of encapsulant 242 to facilitate the formation of wire bond connections.

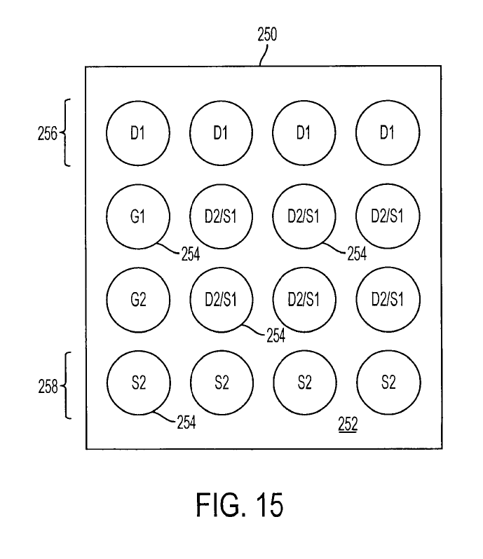

FIG. 15 illustrates a top view of a substrate including dual monolithic integrated lateral MOSFETs with integrated Schottky diodes, the substrate is configured for bump interconnection. In one embodiment, the integrated lateral power MOSFETs having integrated Schottky diodes of the circuit of FIG. 13 are formed over a surface of substrate 250 using the present methods. Die passivation film 252 (shown as 197 on FIG. 10) is formed over a top surface of substrate 250 and is patterned or etched to expose a plurality of bump interconnect sites 254. UBM is formed over each bump interconnect site 254 to facilitate the formation of solder bumps. In one embodiment, the UBM includes a wetting layer, barrier layer, and adhesive layer. The top row 256 of interconnect sites 254 provides a first drain connection D1 for the circuit formed over substrate 250. The bottom row 258 of interconnect sites 256 provide a second source connection S2 for the circuit formed over substrate 250. A first and second gate connection G1 and G2 for the device are formed in a center of the left column of interconnect sites 254. The remaining interconnect sites 254 form a second drain and first source connection D2/S1 for the device. This configuration of interconnect sites 254 groups together connections sites providing similar functionality to simplify the process of forming connections between the interconnect sites 254 of the device and other system components. By grouping all of the drain, gate, source and combined drain and source connections together, other system components can be connected to the interconnect sites 254 using simplified interconnect routing. Furthermore, because the drain and source connections are provided by a plurality of interconnect sites 254, there is redundancy in the case that one of the bump connections fails. Although a single interconnect site 254 is provided for each of the device's gate terminals, the gate connection sites are formed within a row or column of the interconnect sites 254, not at a corner, and minimizes the likelihood of a connection failure.

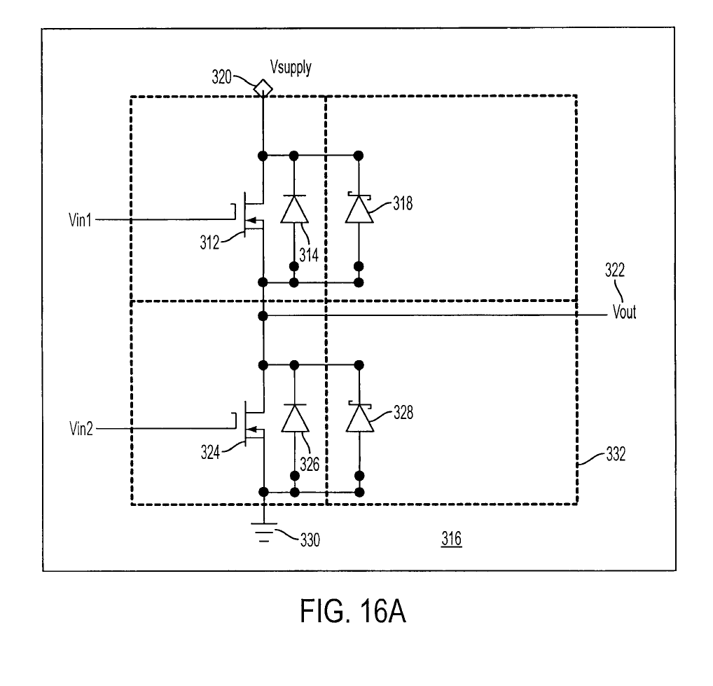

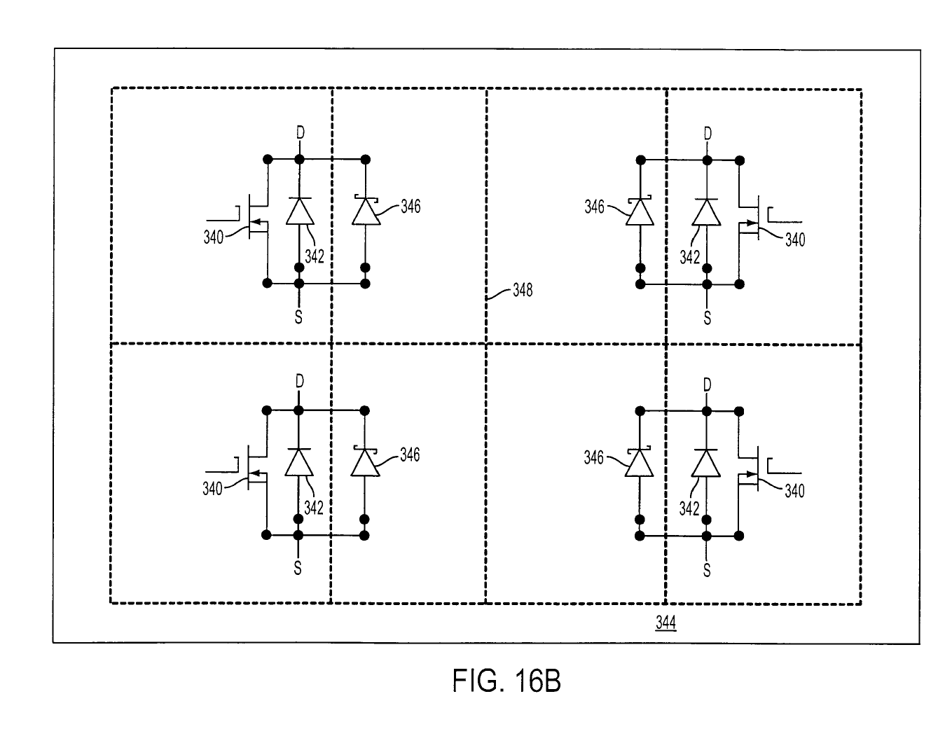

FIG. 16a illustrates an example substrate layout with dual lateral power MOSFETs having integrated Schottky diodes configured in a buck regulator topology. MOSFET 312 having body diode 314 is formed over substrate 316. Schottky diode 318 is formed over substrate 316 and electrically connected to MOSFET 312. Specifically, the drain of MOSFET 312 is connected to the cathode of diode 318 which are both, in turn, connected to voltage supply 320. The source of MOSFET 312 is connected to the anode of diode 318 which are both, in turn connected to output 322. MOSFET 324 having body diode 326 is formed over substrate 316. Schottky diode 328 is formed over substrate 316 and electrically connected to MOSFET 324. Specifically, the drain of MOSFET 324 is connected to the cathode of diode 328 which are both, in turn, connected to output 322. The source of MOSFET 324 is connected to the anode of diode 328 which are both, in turn connected to ground or low voltage 330. Insulated trenches 332 are formed in substrate 316 to electrically isolate each of the devices.

FIG. 16b illustrates a substrate layout that includes multiple lateral power MOSFETs with integrated Schottky diodes. FIG. 16b shows an example layout of the MOSFET and Schottky diode devices on substrate 344. A plurality of MOSFETs 340 having body diodes 342 are formed over substrate 344. A plurality of Schottky diodes 346 is also formed over the substrate. MOSFETs 340 are interconnected with Schottky diodes 346 using chip metallization or another electrical interconnection structure. Insulated trenches 348 are formed in the substrate to electrically isolate each of the devices.

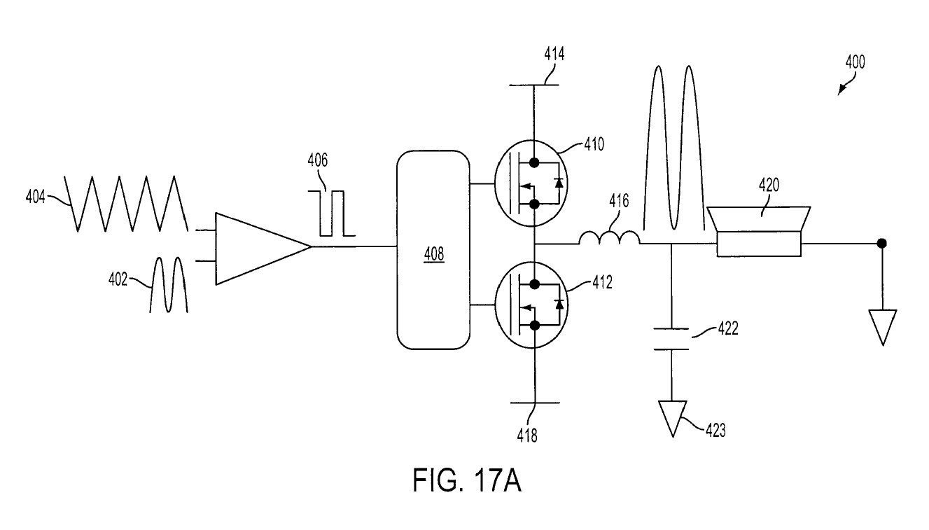

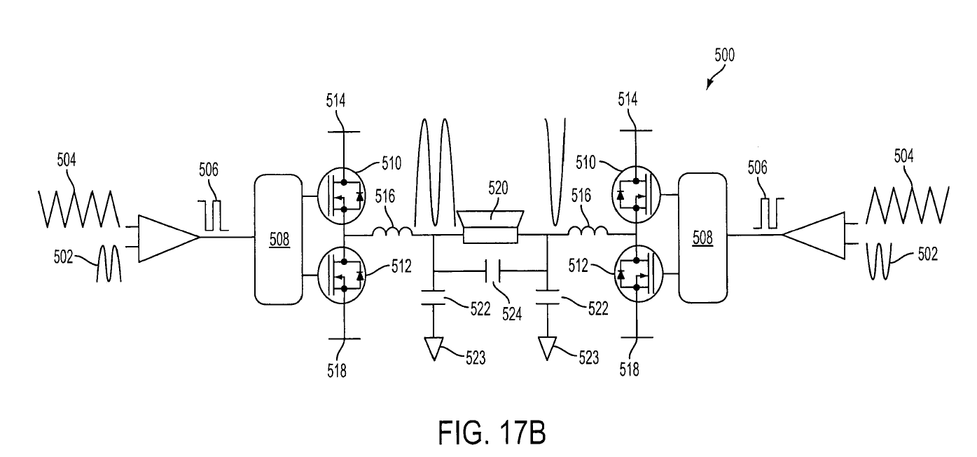

FIGS. 17a-17b illustrate audio amplifier circuits implemented using lateral power MOSFETs with integrated Schottky diodes. FIG. 17a illustrates a class D audio amplifier output stage 400 implemented as a half-bridge amplifier. In FIG. 17a, an input audio signal 402 is combined with an input triangle wave 404 to form PWM signal 406 which is communicated to driver 408. Driver 408 controls the operation of MOSFETs 410 and 412 by controlling a voltage supplied to the gate terminals of MOSFETs 410 and 412. MOSFETs 410 and 412 include lateral power MOSFETs having integrated Schottky diodes. The drain terminal of MOSFET 410 is connected to voltage supply 414. The source terminal of MOSFET 410 is connected to a first terminal of inductor 416 and the drain terminal of MOSFET 412. The source terminal of MOSFET 412 is connected to ground or low voltage supply 418. A second terminal of inductor 416 is connected to a first terminal of capacitor 422 and speaker 420. A second terminal of capacitor 422 is connected to ground or low voltage source 423. Because MOSFETs 410 and 412 have a reduced reverse recovery time, amplifier 400 has a lower total harmonic distortion (THD). Furthermore, the frequency of input triangle wave 404 can be increased to a level above the amplitude-modulated (AM) band to provide additional fidelity and physical size improvements.

FIG. 17b illustrates a full bridge class D audio amplifier output stage 500. Amplifier 500 includes lateral power MOSFETs with integrated Schottky diodes. In FIG. 17b, an input audio signal 502 is combined with input triangle waves 504 to form PWM signals 506 which are communicated to drivers 508. Drivers 508 control the operation of MOSFETs 510 and 512 by controlling a voltage supplied to the gate terminals of MOSFETs 510 and 512. MOSFETs 510 and 512 include lateral power MOSFETs having integrated Schottky diodes. The drain terminals of MOSFETs 510 are connected to voltage supplies 514. The source terminals of MOSFETs 510 are connected to first terminals of inductors 516 and the drain terminals of MOSFETs 512. The source terminals of MOSFETs 512 are connected to ground or low voltage supplies 518. Second terminals of inductors 516 are connected to first terminals of capacitors 522, capacitor 524 and speaker 520. Second terminals of capacitors 522 are connected to ground or low-voltage terminals 523. Because the MOSFETs have a reduced reverse recovery time, amplifier 500 has a lower total harmonic distortion (THD). Furthermore, the frequency of input triangle waves 504 can be increased to a level above the AM band to provide additional fidelity and physical size improvements.

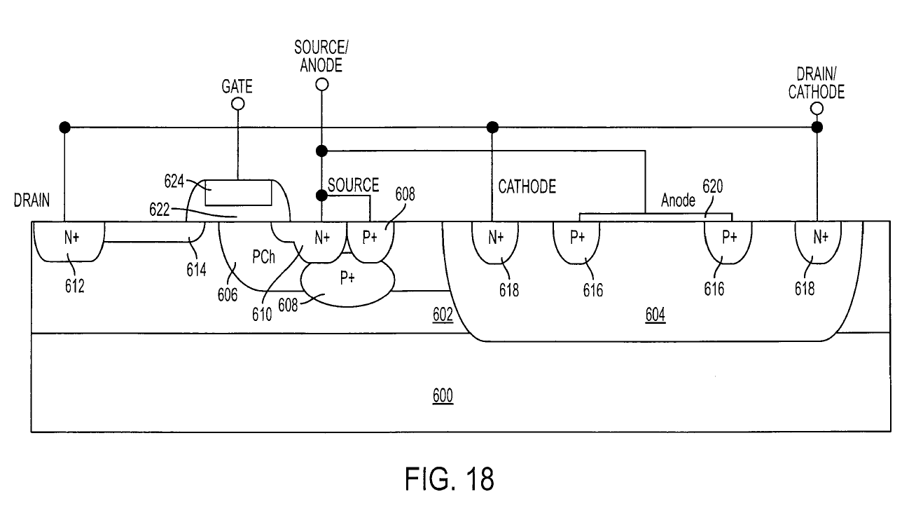

FIG. 18 illustrates a cross-sectional view of a second embodiment of a lateral power MOSFET with an integrated Schottky diode. The lateral power MOSFET and Schottky diode may be formed monolithically onto the same substrate using the semiconductor device fabrication processes described above. Substrate 600 is made of p-type semiconductor material and provides structural support to the device. P− well region 602 is formed within substrate 600. N− well region 604 is formed within substrate 600 using photolithography and implantation. Body region 606 made with P-type material is formed over or above P− well region 602. P+ body 608 and N+ source region 610 are formed over or above P-type body region 606. In one embodiment, P+ body 606 includes a P+ plug region formed below N+ source region 610. N− drift region 614 and N+ drain region 612 are formed above P− well region 602. Anode regions 616 of the Schottky diode are formed with P-type material over or above N− well region 604. N+ cathode regions 618 are formed within N− well region 604 using an implantation or other deposition process. Metal layer 620 is deposited over P+ regions 616 to form the metal anode of the diode. Metal layer 620 includes a conductive material such as Ti, Ni, Pt, Au, Ag, Al and W and may be formed as a metal-silicide or metal-Si layer. Oxide layer 622 is formed over N+ source region 610, P-type body region 606, and N− drift region 614. Gate region 624 is formed over oxide layer 622.

Terminals are connected to one or more of the structures formed over substrate 600 to form interconnects for the lateral power MOSFET with integrated Schottky diode device. N+ drain region 612 of the MOSFET is connected to the N+ cathode regions 618 of the Schottky diode to form a combined drain/cathode terminal for the device. N+ source region 610, P+ source region 608 and metal anode 620 are connected to form a combined source/anode terminal for the device. Finally, a terminal is connected to gate region 624 to form a gate terminal for the device. External system components may be connected to the terminals and placed in electronic communication with the lateral power MOSFET with integrated Schottky diode device.

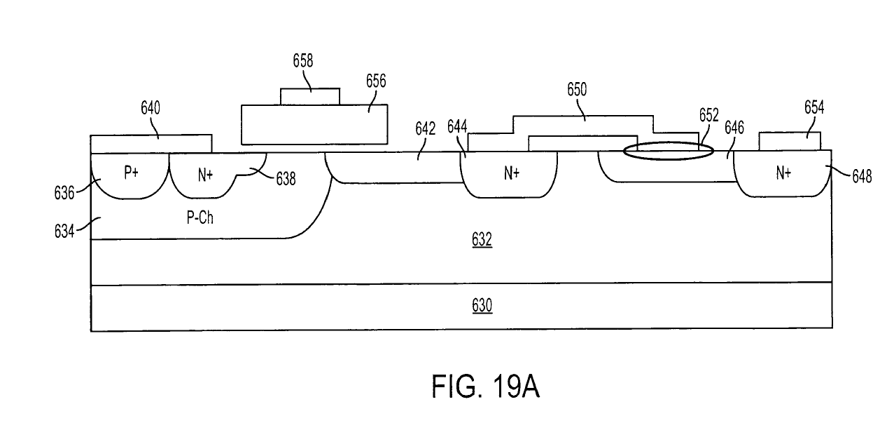

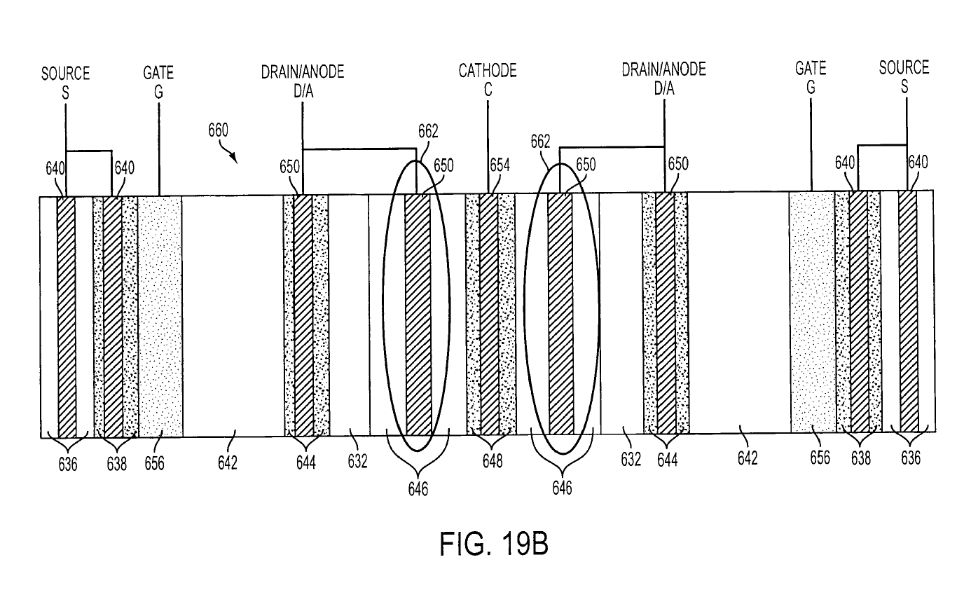

FIGS. 19a and 19b illustrate views of a third embodiment of a lateral power MOSFET with an integrated Schottky diode. FIG. 19a illustrates a cross-sectional view of a substrate including a MOSFET and integrated Schottky diode. Substrate 630 is made of p-type semiconductor material and provides structural support to the device. P− well region 632 is formed within substrate 630. Body region 634 made with P− type material is formed over or above P− well region 632. P+ source 636 and N+ source region 638 are formed over or above P− type body region 634. N+ source region 638 may include a LDD region. Terminal 640 is deposited over P+ region 636 and N+ source region 638 to form a source terminal for the device. Terminal 640 includes a conductive material such as Ti, Ni, Pt, Au, Ag, Al and W and may be deposited using a photolithography and etching process. N− drift regions 642 and 646 and N+ regions 644 and 648 are formed above P− well region 632. Terminal 650 is patterned and deposited over substrate 630 and electrically connects N+ region 644 and N− drift region 646. Terminal 650 includes a conductive material and forms the metal-semiconductor interface of the Schottky diode (indicated by circle 652). In one embodiment, terminal 650 includes Ti and forms a Ti—Si junction between terminal 650 and N− drift region 646. Terminal 650 forms a combined drain/anode terminal for the device. Terminal 654 is patterned and deposited over substrate 630 and is electrically connected to N+ region 648. Terminal 654 includes a conductive material and forms a cathode terminal for the device. Gate oxide 656 is thermally grown over N+ region 638, body region 634 and N− drift region 642. Terminal 658 is deposited over gate oxide 656 to form a gate terminal for the device. Terminal 658 includes a conductive material such as Ti, Ni, Pt, Au, Ag, Al and W.

FIG. 19b illustrates a top view of a substrate including two of the lateral power MOSFETs with integrated Schottky diodes of FIG. 19a. The lateral power MOSFET with integrated Schottky diode is formed as a repeating pattern of source, gate, and drain/anode conduction fingers. FIG. 19b illustrates a top view of two devices configured in mirror-image layouts with the cathode terminals of both devices meeting in a center portion of substrate 660. In FIG. 19b, the repeating pattern includes P+ region 636 and N+ region 638 which form the source of the lateral power MOSFET. Terminals 640 are connected to P+ region 636 and N+ region 638 and provides a source terminal for the device. Gate region 656 is formed over substrate 660. A terminal is connected to gate region 656 to form a gate terminal for the device. N− drift region 642 is formed between gate region 656 and N+ region 644. N+ region 644 forms the drain of the lateral power MOSFET. P-well region 632 provides isolation between N+ region 644 and N− drift region 646. Terminal 650 is deposited over N+ region 644, P− well region 632 and N− drift region 646 to form a combined drain/anode terminal for the device. Terminal 650 includes a conductive material and forms the metal-semiconductor interface of the Schottky diode (indicated by circle 662). N+ region 648 is formed over a central portion of substrate 660 and forms a combined cathode for each Schottky diode. Terminal 654 is formed over N+ region 648 and forms a cathode terminal for the lateral power MOSFET with integrated Schottky diode devices.

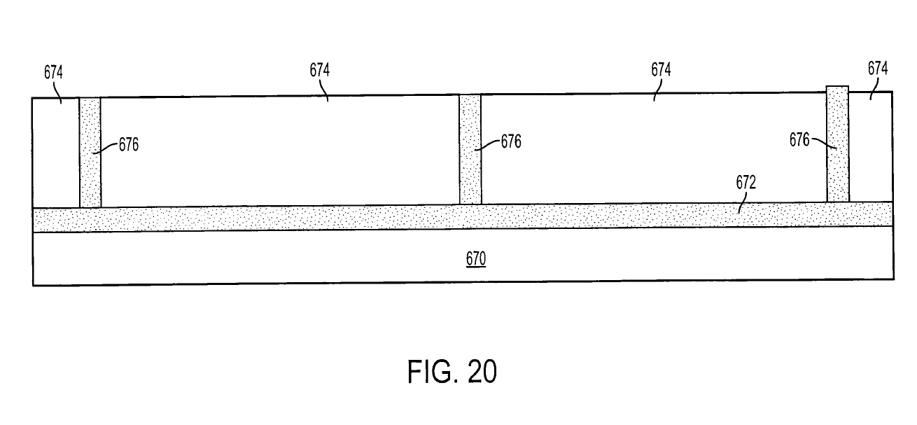

FIG. 20 illustrates a cross-sectional view of a substrate having oxide filled trenches for forming multiple monolithic lateral power MOSFETs with integrated Schottky diodes. Substrate 670 is made of p-type semiconductor material and provides structural support to the device. Insulation layer 672 is formed over substrate 670. In one embodiment, insulation layer 672 is formed by depositing an insulative material over a surface of substrate 670 using a chemical vapor deposition, physical vapor deposition or other deposition or implantation process. Insulation layer 672 provides electrical insulation between substrate 670 and the devices formed over substrate 670 above insulation layer 672 and minimizes the parasitic device capacitance that would otherwise be generated by substrate 670.

A second p-type substrate 674 is bonded over insulation layer 672. In one example bonding process, a layer of SiO2 is formed over a surface of a separate substrate 674 using a thermal oxidation process. Substrate 674 is then inverted and the layer of SiO2 formed over substrate 674 is bonded to insulation layer 672 to connect substrates 670 and 674. After bonding, substrate 674 may be planarized to a particular height, depending upon the application. Trenches are formed in substrate 674 using a laser drilling, or another etching process to expose a portion of insulation layer 672. Insulative material such as SiO2 is deposited into the trenches to form insulating trenches 676. Trenches 676, in combination with insulation layer 672, form electrically isolated regions of wafer 674 over which lateral power MOSFET with integrated Schottky diodes may be formed. By isolating each of the lateral power MOSFET with integrated Schottky diode devices within trenches 676 and insulation layer 672, the performance of each device is maximized and parasitic capacitance between devices is minimized.

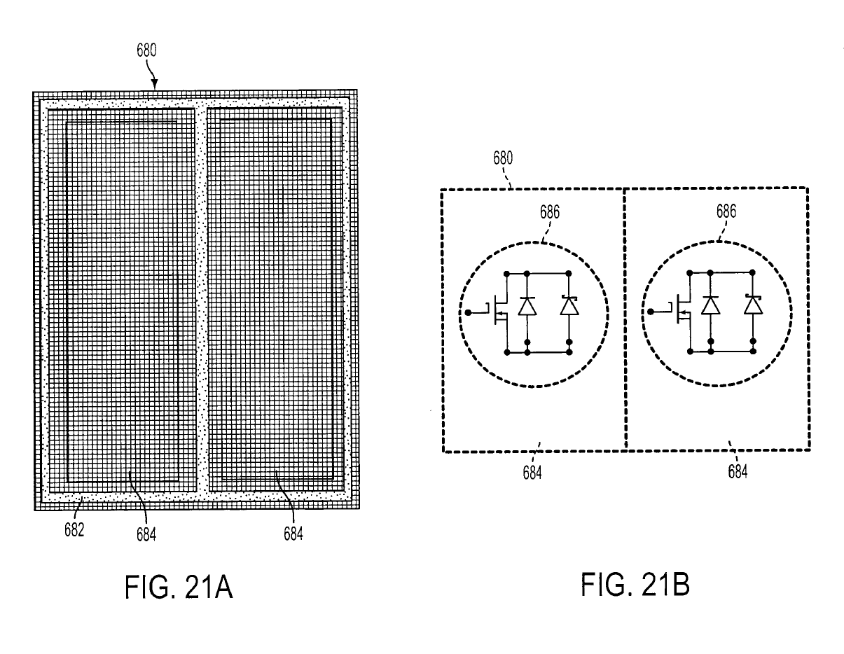

FIGS. 21a and 21b illustrate dual lateral power MOSFETs with integrated Schottky diodes that are formed monolithically over a substrate and are electrically isolated by insulation trenches. FIG. 21a illustrates a top view of substrate 680. Insulation trenches 682 are formed within substrate 680 to defined electrically insulated regions 684 over which electronic devices may be formed. As shown in FIG. 21b, a lateral power MOSFET with integrated Schottky diode device (indicated by circles 686) is formed over each of the electrically insulated regions 684 using the methods described above. With reference to FIG. 21b, the devices are not interconnected, however traces may be formed over substrate 680 to electrically interconnect the devices.

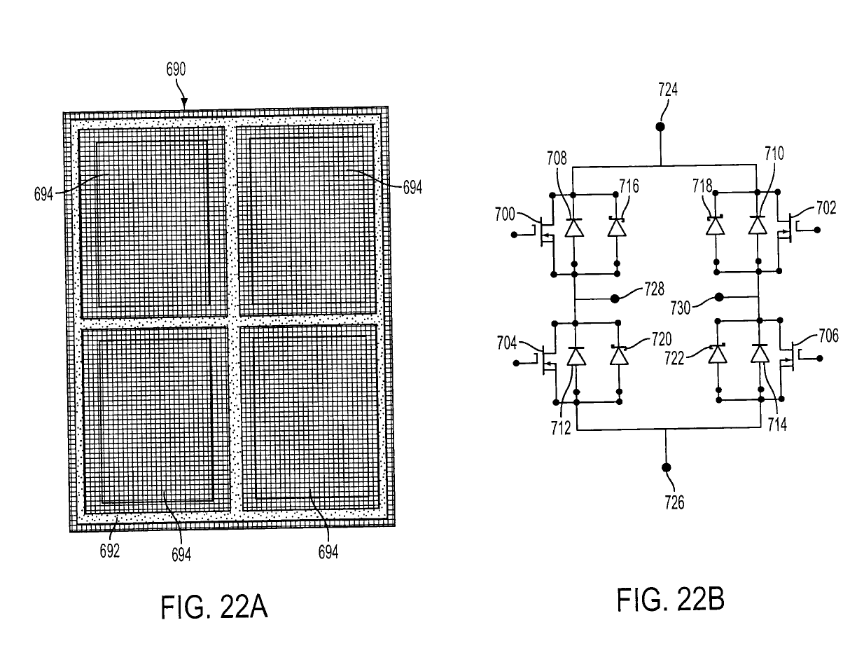

FIGS. 22a and 22b illustrate an H-bridge driver including four lateral power MOSFETs with integrated Schottky diodes formed over a substrate. FIG. 22a illustrates a top view of substrate 690. Insulation trenches 692 are formed within substrate 690 to defined electrically insulated regions 694 over which electronic devices may be formed. A lateral power MOSFET with integrated Schottky diode is formed within each electrically insulated region 694 using the present methods. The devices are then interconnected using conductive traces to form an H-bridge driver. FIG. 22b illustrates a schematic diagram of the circuit formed within substrate 690. MOSFETs 700, 702, 704, and 706 are formed over substrate 690, each in an electrically isolated region. Each MOSFET includes one of body diodes 708, 710, 712, and 714 and integrated Schottky diodes 716, 718, 720 and 722. The anodes of each Schottky diode are connected to the source terminal of each MOSFET. Similarly the cathodes of each Schottky diode are connected to the drain terminal of each MOSFET. The source terminals of MOSFETs 704 and 706 are connected to low-voltage or ground terminal 726. The drain terminal of MOSFET 704 is connected to the source terminal of MOSFET 700 and output port 728. The drain terminal of MOSFET 706 is connected to the source terminal MOSFET 702 and to output port 730. The drain terminals of MOSFETs 700 and 702 are connected to high-voltage or power terminal 724.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first substrate including a first semiconductor material;
an insulating layer disposed over an entire surface of the first substrate;
a second substrate disposed over a surface of the insulating layer, wherein the insulating layer electrically isolates the second substrate from the first substrate, the second substrate including a second semiconductor material;
a plurality of insulating trenches disposed in the second substrate and extending down to the insulating layer, wherein the insulating trenches electrically isolate a first region of the second substrate from a second region of the second substrate;
a lateral metal-oxide-semiconductor field-effect transistor (MOSFET) disposed within the first region;
a Schottky diode disposed within the second region;
a first electrical connection that electrically connects a first terminal of the lateral MOSFET to a plurality of anode regions of the Schottky diode, the first electrical connection disposed over a surface of the second substrate; and
a second electrical connection that electrically connects a second terminal of the lateral MOSFET to a plurality of cathode regions of the Schottky diode, the second electrical connection disposed over the surface of the second substrate.

2. The semiconductor device of claim 1, further comprising P+ regions disposed over or above the anode regions, the anode regions comprising a P-type material.

3. The semiconductor device of claim 2, wherein the Schottky diode comprises a metal layer disposed on the surface of the second substrate and above the anode regions.

4. The semiconductor device of claim 1, wherein the cathode regions comprise N+ regions.

5. The semiconductor device of claim 4, wherein the second electrical connection contacts the cathode regions at the surface of the second substrate.

6. A semiconductor device, comprising:
a first substrate;
an insulating layer disposed over the first substrate;
a second substrate disposed over the insulating layer, wherein the insulating layer provides electrical isolation between the first and second substrates;
an insulating trench disposed in the second substrate down to the insulating layer, the insulating trench electrically isolating a first region of the second substrate from a second region of the second substrate;
a lateral metal-oxide-semiconductor field-effect transistor (MOSFET) disposed within the first region;
a Schottky diode disposed within the second region;
a first electrical connection that electrically connects a first terminal of the lateral MOSFET to a plurality of anode regions of the Schottky diode, the first electrical connection disposed over a surface of the second substrate; and
a second electrical connection that electrically connects a second terminal of the lateral MOSFET to a plurality of cathode regions of the Schottky diode, the second electrical connection disposed over the surface of the second substrate.

7. The semiconductor device of claim 6, the second region comprising:
a N− well region, the anode regions of the diode and the cathode regions of the diode disposed within the N− well region; and
a plurality of P+ regions, each of the P+ regions disposed over or above one of the anode regions.

8. The semiconductor device of claim 7, wherein the Schottky diode comprises a metal layer disposed on a surface of the second substrate within the second region, the metal layer abutting the P+ regions.

9. The semiconductor device of claim 8, wherein the anode regions comprise a P-type material.

10. The semiconductor device of claim 6, wherein the first region does not include a N− well region.

11. The semiconductor device of claim 7, wherein the anode regions are disposed in a center area of the second region, and wherein the cathode regions are disposed in a peripheral area of the second region.

12. The semiconductor device of claim 6, wherein the insulating layer comprises silicon dioxide.

13. A semiconductor device, comprising:
a first substrate;
an insulating layer formed over an entire surface of the first substrate;
a second substrate including a second semiconductor material disposed over the insulating layer, wherein the insulating layer provides electrical isolation between the first and second substrates;
an insulating trench formed through the second substrate to the insulating layer to form first and second electrically isolated regions;
a lateral field-effect transistor (FET) formed within the first electrically isolated region;
a diode formed within the second electrically isolated region;
a first electrical connection between a first terminal of the lateral FET and a plurality of anode regions of the diode, the first electrical connection formed over a surface of the second substrate; and
a second electrical connection between a second terminal of the lateral FET and a plurality of cathode regions of the diode, the second electrical connection formed over the surface of the second substrate.

14. The semiconductor device of claim 13, wherein the diode comprises a Schottky diode.

15. The semiconductor device of claim 14, wherein the Schottky diode comprises a metal layer disposed on the surface of the second substrate, and disposed in contact with the anode regions.

16. The semiconductor device of claim 14, the second electrically isolated region comprising a N− well region.

17. The semiconductor device of claim 16, wherein the cathode regions comprise N+ regions disposed within the N− well region.

18. A semiconductor device, comprising:
a substrate having a first region and a second region, the first region electrically isolated from the second region;
a lateral field-effect transistor (FET) disposed within the first region, the lateral FET including a first terminal and a second terminal;
a diode disposed within the second region, the diode including a plurality of anode regions and a plurality of cathode regions;
a first electrical connection between the first terminal of the lateral FET and the anode regions of the diode, the first electrical connection disposed over a surface of the substrate; and
a second electrical connection between the second terminal of the lateral FET and the cathode regions of the diode, the second electrical connection disposed over the surface of the substrate.

19. The semiconductor device of claim 18, wherein the cathode regions of the diode are disposed further from a center of the second region than the anode regions of the diode.

20. The semiconductor device of claim 19, the diode comprising a metal layer that is disposed on the surface of the substrate and over the anode regions.

21. The semiconductor device of claim 20, wherein the first electrical connection contacts the metal layer.

22. The semiconductor device of claim 21, wherein the substrate comprises a layer of silicon dioxide (SiO2).

23. The semiconductor device of claim 21, wherein the substrate comprises:
a first substrate having a first layer of silicon dioxide; and
a second substrate having a second layer of silicon dioxide, wherein the first layer of silicon dioxide is bonded to the second layer of silicon dioxide.

24. The semiconductor device of claim 21, wherein the diode comprises a Schottky diode.
